(19) United States
(12) Patent Application Publication
(10) Pub. No.: US 2026/0182054 A1
(43) Pub. Date: Jun. 25, 2026

(54) IMAGE SENSOR AND METHOD OF FABRICATING THE SAME

(71) Applicant: SAMSUNG ELECTRONICS CO., LTD., Suwon-si (KR)

(72) Inventors: Kijoong YOON, Goyang-si (KR); Keewon KIM, Suwon-si (KR); Minkwan KIM, Hwaseong-si (KR); Sanghoon AHN, Seongnam-si (KR); Hajin LIM, Seoul (KR); Jongmin JEON, Suwon-si (KR); Taeksoo JEON, Hwaseong-si (KR); Jaesung HUR, Yongin-si (KR)

(73) Assignee: SAMSUNG ELECTRONICS CO., LTD., Suwon-si (KR)

(21) Appl. No.: 19/535,316

(22) Filed: Feb. 10, 2026

Related U.S. Application Data
(62) Division of application No. 18/046,491, filed on Oct. 13, 2022.

(30) Foreign Application Priority Data
Nov. 26, 2021 (KR) 10-2021-0166013

(51) Int. Cl. H10F 39/00; H10F 39/18

(52) U.S. Cl. CPC H10F 39/024; H10F 39/182; H10F 39/805; H10F 39/8053; H10F 39/8063; H10F 39/807

(57) ABSTRACT

A method of fabricating an image sensor includes providing a substrate that includes a plurality of pixel regions, forming an anti-reflection layer on the substrate, forming color filters on the anti-reflection layer, where the color filters are spaced apart from each other by openings, forming pyrolytic polymer patterns between the color filters that fill the openings, forming a capping layer on the color filters and the pyrolytic polymer patterns, and performing a thermal treatment process that removes the pyrolytic polymer patterns and forms air gap regions between the color filters.

### CROSS-REFERENCE TO RELATED APPLICATIONS

This application is a Divisional of U.S. patent application Ser. No. 18/046,491 filed on Oct. 13, 2022, which claims priority under 35 U.S.C. § 119 from Korean Patent Application No. 10-2021-0166013, filed on Nov. 26, 2021 in the Korean Intellectual Property Office, the contents of which are herein incorporated by reference in their entirety.

### TECHNICAL FIELD

Embodiments of the present disclosure are directed to an image sensor and a method of fabricating the same, and in particular, to a complementary metal oxide semiconductor (CMOS) image sensor.

### DISCUSSION OF THE RELATED ART

An image sensor is a semiconductor device that converts an optical image into electric signals. High-performance image sensors are used in a variety of applications, such as digital cameras, camcorders, personal communication systems, gaming machines, security cameras, micro-cameras for medical applications, and/or robots. Image sensors may be classified into two types: a charge coupled device (CCD) type and a complementary metal-oxide-semiconductor (CMOS) type. In general, a CMOS-type image sensor is called “CIS”. A CIS device includes a plurality of two-dimensionally-arranged pixels. Each of the pixels includes a photodiode (PD) that coverts incident light into an electrical signal. The pixels are defined by a deep isolation pattern disposed therebetween.

### SUMMARY

An embodiment of the inventive concept provides an image sensor with an increased optical sensitivity and a method of fabricating the same.

According to an embodiment of the inventive concept, a method of fabricating an image sensor includes providing a substrate that includes a plurality of pixel regions, forming an anti-reflection layer on the substrate, forming color filters on the anti-reflection layer, where the color filters are spaced apart from each other by openings, forming pyrolytic polymer patterns between the color filters that fill the openings, forming a capping layer on the color filters and the pyrolytic polymer patterns, and performing a thermal treatment process that removes the pyrolytic polymer patterns and forms air gap regions between the color filters.

According to an embodiment of the inventive concept, a method of fabricating an image sensor includes providing a substrate that includes a plurality of pixel regions, sequentially forming an anti-reflection layer and a passivation layer on the substrate, forming color filters on the passivation layer, forming pyrolytic polymer patterns between the color filters, forming a capping layer on the color filters and the pyrolytic polymer patterns, and performing a thermal treatment process that removes the pyrolytic polymer patterns and forms an air gap region that is a space between the color filters and between the passivation and capping layers. The pyrolytic polymer patterns include a carbon-based polymer.

According to an embodiment of the inventive concept, an image sensor includes a substrate that includes a plurality of pixel regions, an anti-reflection layer disposed on the substrate, a passivation layer disposed on the anti-reflection layer, color filters disposed on the passivation layer and on the pixel regions and that are spaced apart from each other by gap regions, a capping layer disposed on the color filters, and micro lenses disposed on the capping layer. The gap regions are spaces between the color filters and between the passivation and capping layers, and a bottom surface of the capping layer may be flat.

### BRIEF DESCRIPTION OF THE DRAWINGS

FIG. 1 is a block diagram of an image sensor according to an embodiment of the inventive concept.

FIG. 2 is a circuit diagram of an active pixel sensor array of an image sensor according to an embodiment of the inventive concept.

FIG. 3 is a plan view of an image sensor according to an embodiment of the inventive concept.

FIG. 4 is a sectional view taken along a line I-I′ of FIG. 3 of an image sensor according to an embodiment of the inventive concept.

FIGS. 5 to 13 are sectional views that illustrate a method of fabricating an image sensor according to an embodiment of the inventive concept and corresponding to the line I-I′ of FIG. 3.

FIGS. 14 to 17 are sectional views that illustrate a method of fabricating an image sensor according to an embodiment of the inventive concept and corresponding to the line I-I′ of FIG. 3.

FIG. 18 is a sectional view taken along the line I-I′ of FIG. 3 of an image sensor according to an embodiment of the inventive concept.

FIG. 19 is a plan view of an image sensor according to an embodiment of the inventive concept.

FIG. 20 is a sectional view taken along a line II-II′ of FIG. 19 of an image sensor according to an embodiment of the inventive concept.

### DETAILED DESCRIPTION

Exemplary embodiments of the inventive concepts will now be described more fully with reference to the accompanying drawings, in which exemplary embodiments are shown.

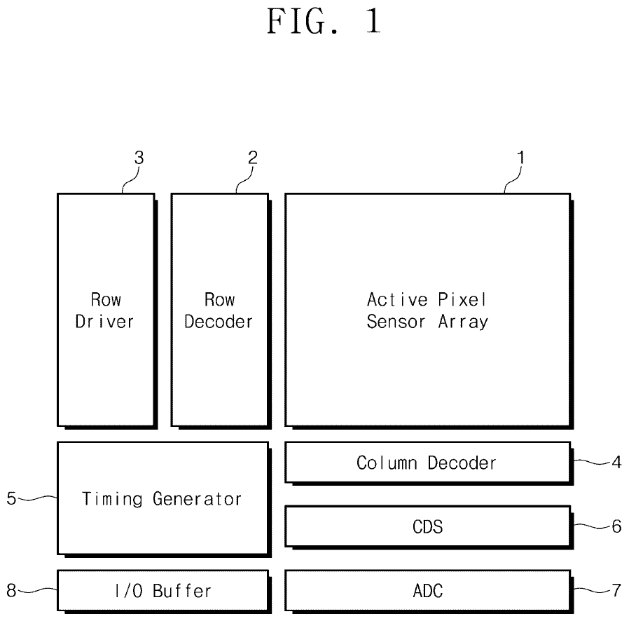

FIG. 1 is a block diagram of an image sensor according to an embodiment of the inventive concept.

Referring to FIG. 1, in an embodiment, an image sensor includes an active pixel sensor array 1, a row decoder (a decoder circuit) 2, a row driver (a driver circuit) 3, a column decoder (a decoder circuit) 4, a timing generator (a generator circuit) 5, a correlated double sampler (CDS) (a sampling circuit) 6, an analog-to-digital converter (a convertor circuit) (ADC) 7, and an input/output (I/O) buffer (a buffer circuit) 8.

The active pixel sensor array 1 includes a plurality of pixels that are two-dimensionally arranged and are used to convert optical signals into electrical signals. The active pixel sensor array 1 is driven by a plurality of driving signals, such as pixel selection signals, reset signals, and charge transfer signals, received from the row driver 3. In addition, the electrical signals that are converted by the active pixel sensor array 1 are provided to the CDS 6.

The row driver 3 provides a plurality of driving signals that are used to drive the pixels to the active pixel sensor array 1, based on results decoded by the row decoder 2. When the pixels are arranged in a matrix pattern, the driving signals are transmitted to respective rows of the pixels.

The timing generator 5 provides a timing signal and a control signal to the row decoder 2 and the column decoder 4.

The CDS 6 receives the electric signals generated by the active pixel sensor array 1 and performs a holding and sampling operation on the received electric signals. In addition, the CDS 6 performs a double sampling operation on a specific noise level and a signal level of the electric signal and then outputs a difference level that corresponds to a difference between the noise and signal levels.

The ADC 7 converts an analog signal that contains information on the difference level outputted from the CDS 6 to a digital signal and outputs the converted digital signal.

The I/O buffer 8 latches the digital signals and then sequentially outputs the latched digital signals to an image signal processing unit based on the result decoded by the column decoder 4.

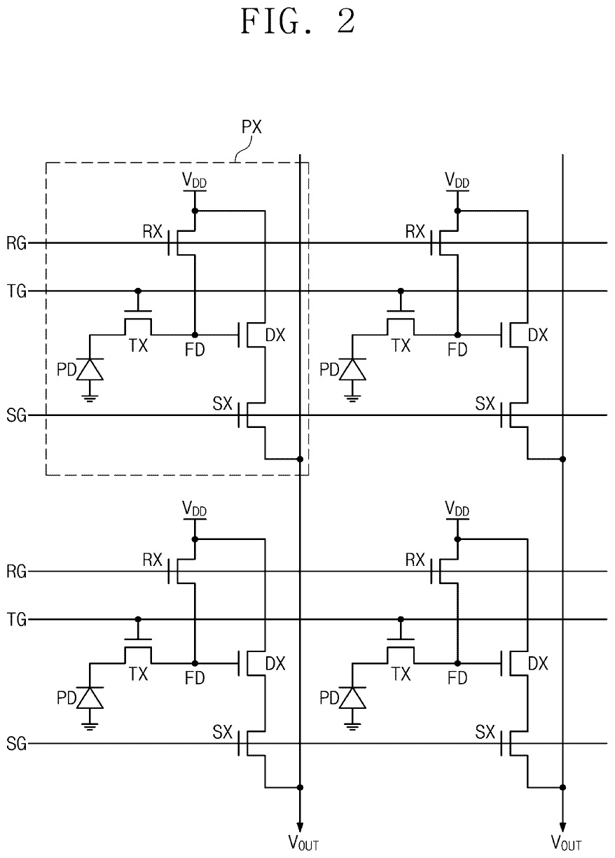

FIG. 2 is a circuit diagram of an active pixel sensor array of an image sensor according to an embodiment of the inventive concept.

Referring to FIGS. 1 and 2, in an embodiment, the active pixel sensor array 1 includes a plurality of pixel regions PX, and the pixel regions PX are arranged in a matrix pattern. Each of the pixel regions PX includes a transfer transistor TX and logic transistors RX, SX, and DX. The logic transistors include a reset transistor RX, a selection transistor SX, and a drive transistor DX. The transfer transistor TX, the reset transistor RX, and the selection transistor SX include a transfer gate TG, a reset gate RG, and a selection gate SG, respectively. Each of the pixel regions PX further includes a photoelectric conversion device PD and a floating diffusion region FD.

The photoelectric conversion device PD generates and holds photocharges whose amount is proportional to an amount of externally incident light. The photoelectric conversion device PD is a photodiode that includes a p-type impurity region and an n-type impurity region. The transfer transistor TX transfers electric charges that are generated in the photoelectric conversion device PD to the floating diffusion region FD. The floating diffusion region FD receives the charges that are generated in the photoelectric conversion device PD and cumulatively stores the charges therein. The drive transistor DX is controlled by the amount of the photocharges that are stored in the floating diffusion region FD.

The reset transistor RX periodically discharges the electric charges stored in the floating diffusion region FD. A drain electrode of the reset transistor RX is connected to the floating diffusion region FD, and a source electrode of the reset transistor RX is connected to a power voltage VDD. If the reset transistor RX is turned on, the power voltage VDD, which is connected to the source electrode of the reset transistor RX, is transmitted to the floating diffusion region FD. Thus, when the reset transistor RX is turned on, the electric charges stored in the floating diffusion region FD are discharged; and the floating diffusion region FD is reset.

The drive transistor DX is a source follower buffer amplifier. The drive transistor DX amplifies a variation in electric potential of the floating diffusion region FD and outputs the amplified signal to an output line Vout.

The selection transistor SX selects a row of the pixel regions PX to be read out during a read operation. When the selection transistor SX is turned on, the power voltage VDD is transmitted to a drain electrode of the drive transistor DX.

FIG. 2 illustrates the unit pixel region PX that includes one the photoelectric conversion device PD and four transistors TX, RX, DX, and SX, but embodiments of the inventive concept are not necessarily limited to this image sensor structure. For example, in an embodiment, one or more of the reset transistor RX, the drive transistor DX, or the selection transistor SX may be shared by adjacent pixel regions PX, and an integration density of the image sensor is increased.

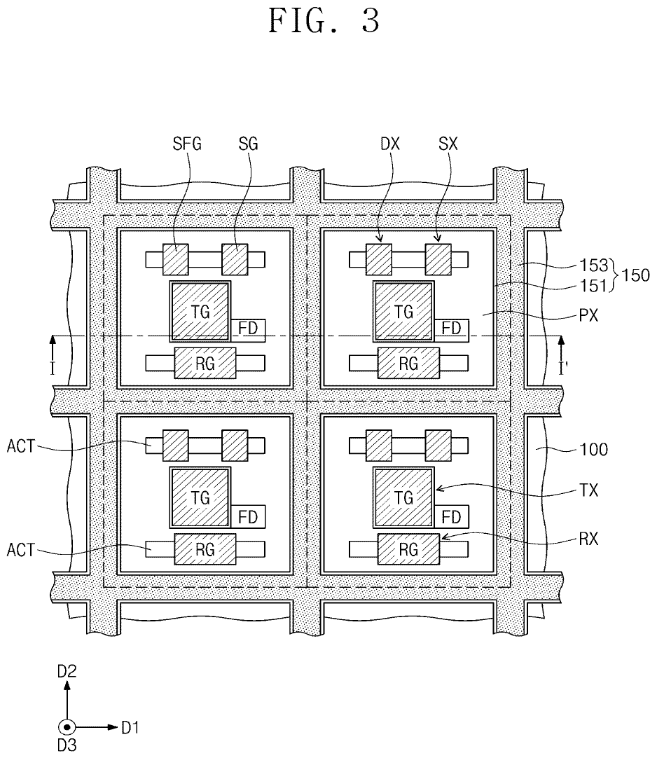

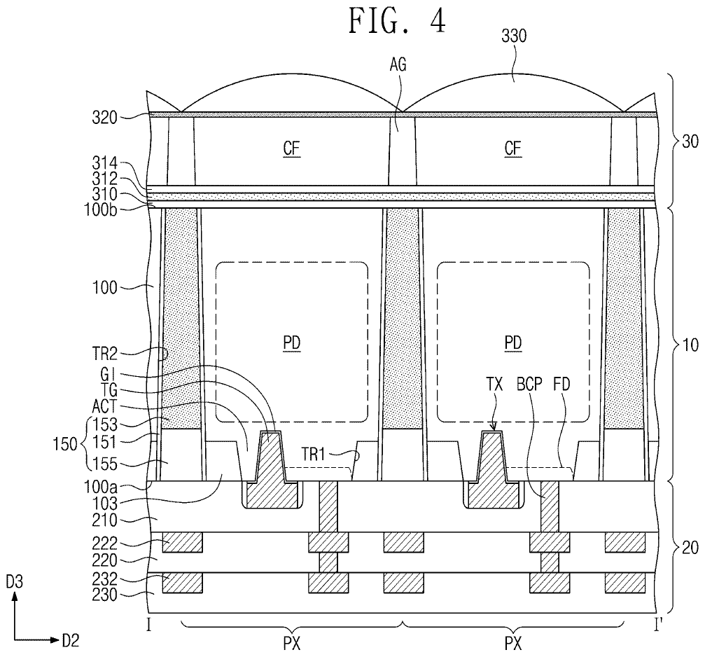

FIG. 3 is a plan view of an image sensor according to an embodiment of the inventive concept. FIG. 4 is a sectional view taken along a line I-I′ of FIG. 3 of an image sensor according to an embodiment of the inventive concept.

Referring to FIGS. 3 and 4, in an embodiment, an image sensor includes a photoelectric conversion layer 10, an interconnection layer 20, and an optically-transparent layer 30. The photoelectric conversion layer 10 is disposed between the interconnection layer 20 and the optically-transparent layer 30.

The photoelectric conversion layer 10 includes a substrate 100. The substrate 100 may be a semiconductor substrate, such as a silicon wafer, a germanium wafer, a silicon-germanium wafer, a II-VI compound semiconductor wafer, or a III-V compound semiconductor wafer, or a silicon-on-insulator (SOI) wafer. The substrate 100 includes a first surface 100a and a second surface 100b that are opposite to each other in a third or thickness direction D3. For example, the first surface 100a of the substrate 100 may be a front surface, and the second surface 100b may be a rear surface. Light is incident into the substrate 100 through the second surface 100b.

The substrate 100 includes the pixel regions PX. When viewed in a plan view, the pixel regions PX are two-dimensionally arranged in plane defined by a first direction D1 and a second direction D2 that are parallel to the second surface 100b of the substrate 100. The first and second directions D1 and D2 are not parallel to each other. The substrate 100 includes a plurality of photoelectric conversion regions PD therein. Hereinafter, the photoelectric conversion region PD refers to a region in which the photoelectric conversion device PD of FIGS. 1 and 2 is disposed. The photoelectric conversion regions PD are located between the first surface 100a and the second surface 100b of the substrate 100. The photoelectric conversion regions PD are respectively provided in the pixel regions PX of the substrate 100.

The substrate 100 is doped to have a first conductivity type, and the photoelectric conversion region PD is doped to have a second conductivity type that differs from the first conductivity type. For example, the first conductivity type may be a p-type, and the second conductivity type may be an n-type. Impurities for the first conductivity type include at least one of aluminum, boron, indium, or gallium. Impurities for the second conductivity type include at least one of phosphorus, arsenic, bismuth, or antimony. The photoelectric conversion region PD and the substrate 100 form a pn junction that serves as a photodiode.

The photoelectric conversion layer 10 includes a shallow isolation pattern 103. The shallow isolation pattern 103 is disposed adjacent to the first surface 100a of the substrate 100. Each of the pixel regions PX includes active regions ACT defined by the shallow isolation pattern 103. The shallow isolation pattern 103 are disposed in a first trench TR1 that is recessed from the first surface 100a of the substrate 100. The shallow isolation pattern 103 is formed of or includes at least one of, for example, silicon oxide, silicon nitride, or silicon oxynitride.

The photoelectric conversion layer 10 includes a deep isolation pattern 150. The deep isolation pattern 150 includes a plurality of deep isolation patterns 150. The deep isolation pattern 150 is disposed in the substrate 100 between the pixel regions PX. The deep isolation pattern 150 penetrates at least a portion of the substrate 100. For example, the deep isolation pattern 150 penetrates the shallow isolation pattern 103 and extends into the substrate 100. The deep isolation pattern 150 is disposed in a second trench TR2. The second trench TR2 defines the pixel regions PX. The second trench TR2 penetrates the shallow isolation pattern 103 and extends toward the second surface 100b of the substrate 100. The greatest width of the second trench TR2 is narrower than the least width of the first trench TR1. In the present specification, a width of an element means a length of the element measured in a direction, such as the second direction D2, that is parallel to the second surface 100b of the substrate 100. When viewed in a plan view, the deep isolation pattern 150 encloses each of the pixel regions PX and has a lattice structure. In an embodiment, the deep isolation pattern 150 extends from the first surface 100a of the substrate 100 toward the second surface 100b of the substrate 100, and a top surface of the deep isolation pattern 150 is substantially coplanar with the second surface 100b of the substrate 100. The deep isolation pattern 150 is formed of or includes an insulating material whose refractive index is lower than that of the substrate 100.

The deep isolation pattern 150 includes an isolation pattern 151, a semiconductor pattern 153, and a gapfill insulating pattern 155. The isolation pattern 151 penetrates at least a portion of the substrate 100. The isolation pattern 151 is interposed between the pixel region PX and the semiconductor pattern 153. The isolation pattern 151 is interposed between the substrate 100 and a side surface of the semiconductor pattern 153 and between the shallow isolation pattern 103 and the gapfill insulating pattern 155. The isolation pattern 151 extends from the side surface of the semiconductor pattern 153 to a side surface of the gapfill insulating pattern 155. The isolation pattern 151 fills a portion of the second trench TR2. The isolation pattern 151 conformally covers inner side surfaces of the second trench TR2. When viewed in a plan view, the isolation pattern 151 encloses each of the pixel regions PX. The isolation pattern 151 includes at least one insulating material, and for example, the isolation pattern 151 is formed of or includes at least one of silicon oxide, silicon oxynitride, or a high-k dielectric material, such as hafnium oxide and/or aluminum oxide.

The semiconductor pattern 153 penetrates at least a portion of the substrate 100. The semiconductor pattern 153 is interposed between the pixel regions PX. The semiconductor pattern 153 fills a portion of the second trench TR2. The semiconductor pattern 153 covers inner side surfaces of the isolation pattern 151 and is in contact with the isolation pattern 151. A top surface of the semiconductor pattern 153 is substantially coplanar with the second surface 100b of the substrate 100. A bottom surface of the semiconductor pattern 153 is located at a higher level than the first surface 100a of the substrate 100. In the present specification, the term ‘level’ means a vertical height measured from the first surface 100a of the substrate 100 in the third direction D3, which is normal to the plane defined by the first and second directions D1 and D2. The semiconductor pattern 153 is formed of or includes at least one conductive material, such as a doped semiconductor material. The semiconductor pattern 153 is formed of or includes a p-type or n-type semiconductor material. For example, the semiconductor pattern 153 is formed of or includes doped polysilicon.

The gapfill insulating pattern 155 is disposed on the semiconductor pattern 153. The gapfill insulating pattern 155 fills a remaining portion of the second trench TR2. The gapfill insulating pattern 155 is disposed in the shallow isolation pattern 103 between the semiconductor pattern 153 and the interconnection layer 20. In an embodiment, the gapfill insulating pattern 155 extends into the substrate 100. The gapfill insulating pattern 155 penetrates the shallow isolation pattern 103 and is in contact with the semiconductor pattern 153. The gapfill insulating pattern 155 is spaced apart from the shallow isolation pattern 103 by the isolation pattern 151. The gapfill insulating pattern 155 is formed of or includes at least one of, for example, silicon oxide, silicon nitride, or silicon oxynitride.

Referring back to FIGS. 3 and 4, in an embodiment, the transfer transistors TX and the logic transistors RX, SX, and DX are disposed on the first surface 100a of the substrate 100. Each of the transistors TX, RX, SX, and DX is disposed on a corresponding active region ACT of each pixel region PX. The transfer transistor TX includes the transfer gate TG on a corresponding active region ACT and the floating diffusion region FD. The transfer gate TG includes a lower portion that is partially inserted in the substrate 100, and an upper portion that is placed at a higher level than the first surface 100a of the substrate 100. A gate dielectric layer GI is interposed between the transfer gate TG and the substrate 100. The floating diffusion region FD is provided in a portion of the corresponding active region ACT that is located at a side of the transfer gate TG. The floating diffusion region FD is doped to have the second conductivity type, such as an n-type, that differs from the first conductivity type of the substrate 100.

The drive transistor DX includes a drive gate SFG provided on a corresponding active region ACT, and the selection transistor SX includes the selection gate SG provided on a corresponding active region ACT. The reset transistor RX includes the reset gate RG provided on a corresponding active region ACT. An additional gate dielectric layer GI is interposed between each of the drive, selection, and reset gates SFG, SG, and RG and the substrate 100.

The interconnection layer 20 is disposed on the first surface 100a of the substrate 100. The interconnection layer 20 includes a first interlayer insulating layer 210, a second interlayer insulating layer 220, and a third interlayer insulating layer 230 that are sequentially stacked on the first surface 100a of the substrate 100. The interconnection layer 20 further includes contact plugs BCP in the first interlayer insulating layer 210, first interconnection patterns 222 in the second interlayer insulating layer 220, and second interconnection patterns 232 in the third interlayer insulating layer 230. The first interlayer insulating layer 210 is disposed on the first surface 100a of the substrate 100 and covers the transistors TX, RX, SX, and DX, and the contact plugs BCP are connected to terminals of the transistors TX, RX, SX, and DX. The contact plugs BCP are connected to corresponding first interconnection patterns 222, and the first interconnection patterns 222 are connected to corresponding second interconnection patterns 232. The first and second interconnection patterns 222 and 232 are electrically connected to the transistors TX, RX, SX, and DX through the contact plugs BCP. Each of the first to third interlayer insulating layers 210, 220, and 230 is formed of or includes an insulating material, and the contact plugs BCP, the first interconnection patterns 222, and the second interconnection patterns 232 are formed of or include conductive materials.

The optically-transparent layer 30 is disposed on the second surface 100b of the substrate 100. The optically-transparent layer 30 includes a plurality of color filters CF and a plurality of micro lenses 330. The optically-transparent layer 30 includes a plurality of air gap regions AG. The optically-transparent layer 30 condenses and filters externally incident light, and provides the light to the photoelectric conversion layer 10.

An insulating layer 310 is provided on the second surface 100b of the substrate 100. The insulating layer 310 covers the second surface 100b of the substrate 100. The insulating layer 310 is formed of or includes at least one of an oxide, a nitride, silicon oxide, silicon nitride, or silicon oxynitride.

An anti-reflection layer 312 is provided on the second surface 100b of the substrate 100. The anti-reflection layer 312 is disposed on the insulating layer 310 and covers the insulating layer 310. The anti-reflection layer 312 is interposed between the insulating layer 310 and a passivation layer 314 to be described below. The anti-reflection layer 312 prevents reflection of light incident into the second surface 100b of the substrate 100, which allows the light to effectively arrive at the photoelectric conversion region PD. In an embodiment, the anti-reflection layer 312 is formed of or includes at least one metal oxide material, such as hafnium oxide or aluminum oxide.

The passivation layer 314 is provided on the second surface 100b of the substrate 100. The passivation layer 314 is disposed on the anti-reflection layer 312 and covers the anti-reflection layer 312. The passivation layer 314 is interposed between the anti-reflection layer 312 and the color filters CF. In an embodiment, the passivation layer 314 is formed of or includes at least one of a metal, such as titanium or tantalum, or a metal nitride, such as titanium nitride or tantalum nitride. The insulating layer 310, the anti-reflection layer 312 and the passivation layer 314 are sequentially stacked between the second surface 100b of the substrate 100 and the color filters CF.

The color filters CF are provided on the second surface 100b of the substrate 100. The color filters CF are disposed on the passivation layer 314. The color filters CF are interposed between the second surface 100b of the substrate 100 and the micro lenses 330. Each of the color filters CF vertically overlap the photoelectric conversion region PD of a corresponding pixel regions PX, e.g., in the third direction D3. Each of the color filters CF is one of a red, green, or blue filter, and the color of a color filter CF is determined based on a position of an underlying unit pixel. However, embodiments are not necessarily limited thereto, and in an embodiment, each of the color filters CF is one of a yellow, magenta, or cyan filter. The color filters CF are two-dimensionally arranged in a plane defined by the first and second directions D1 and D2.

A capping layer 320 is provided on the second surface 100b of the substrate 100. The capping layer 320 is disposed on the color filters CF and covers the color filters CF. The capping layer 320 is interposed between the color filters CF and the micro lenses 330. Top and bottom surfaces of the capping layer 320 are substantially flat. The capping layer 320 is formed of or includes at least one of an oxide, a nitride, silicon oxide, silicon nitride, or silicon oxynitride.

A space between the color filters CF and between the passivation and capping layers 314 and 320 is the air gap region AG. The air gap region AG may contain air. For example, each air gap region AG is enclosed by the color filters CF, the passivation layer 314, and the capping layer 320. The air gap region AG is provided between the pixel regions PX. The air gap region AG vertically overlaps the deep isolation pattern 150. The air gap region AG guide light that is incident through the second surface 100b of the substrate 100 such that the light is incident into the photoelectric conversion region PD.

The micro lenses 330 are provided on the second surface 100b of the substrate 100. The micro lenses 330 are disposed on the capping layer 320. Each of the micro lenses 330 vertically overlaps the photoelectric conversion region PD of a corresponding pixel region PX, e.g., in the third direction D3. The micro lenses 330 have a convex shape that is curved away from the color filters and effectively condense incident light into the pixel regions PX.

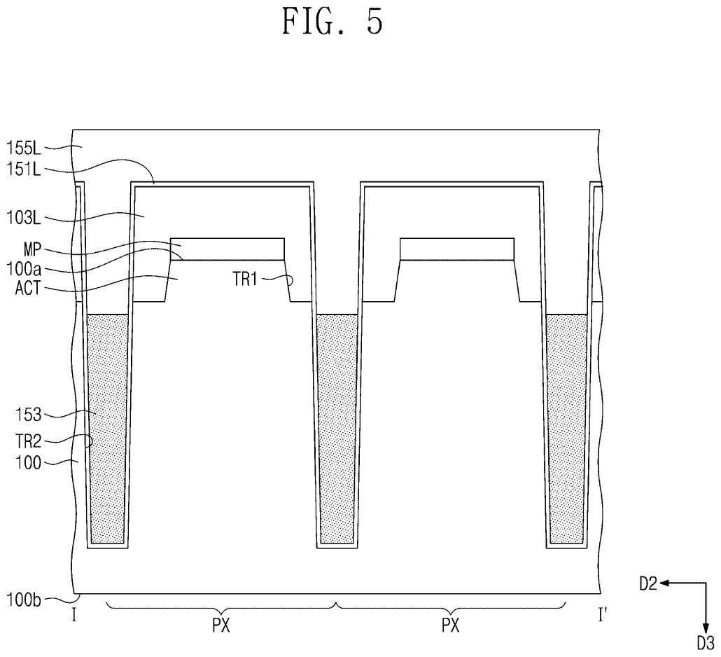

FIGS. 5 to 13 are sectional views that illustrate a method of fabricating an image sensor according to an embodiment of the inventive concept and corresponding to the line I-I′ of FIG. 3. For the sake of brevity, the same element as in an image sensor previously described with reference to FIGS. 1 to 4 may be identified by the same reference number while omitting a repeated description thereof.

Referring to FIGS. 3 and 5, in an embodiment, the substrate 100, which includes the first surface 100a and the second surface 100b that are opposite to each other, is provided. The first trench TR1 is formed adjacent to the first surface 100a of the substrate 100. The formation of the first trench TR1 includes forming a first mask pattern MP on the first surface 100a of the substrate 100 and etching the substrate 100 using the first mask pattern MP as an etch mask. The first trench TR1 defines the active regions ACT in the substrate 100.

A device isolation layer 103L is formed on the first surface 100a of the substrate 100. The device isolation layer 103L fills the first trench TR1 and covers the first mask pattern MP. The device isolation layer 103L is formed of or includes at least one of, for example, silicon oxide, silicon nitride, or silicon oxynitride.

The second trench TR2 is formed in the substrate 100. The formation of the second trench TR2 includes forming a second mask pattern that defines a position and shape of the second trench TR2 on the device isolation layer 103L, and etching the device isolation layer 103L and the substrate 100 using the second mask pattern as an etch mask. A bottom surface of the second trench TR2 is located at a higher level than the second surface 100b of the substrate 100. The pixel regions PX are defined in the substrate 100 by the second trench TR2. The pixel regions PX respectively include the active regions ACT that are defined by the first trench TR1.

An isolation layer 151L is formed on the substrate 100. The isolation layer 151L conformally covers inner side surfaces and a bottom surface of the second trench TR2. The isolation layer 151L covers the device isolation layer 103L. The isolation layer 151L is formed of or includes at least one oxide material, and in an embodiment, the isolation layer 151L is formed of or includes at least one of silicon oxide, silicon oxynitride, or a high-k dielectric material, such as hafnium oxide and/or aluminum oxide.

The semiconductor pattern 153 is formed in the second trench TR2. The semiconductor pattern 153 fills a lower portion of the second trench TR2. The formation of the semiconductor pattern 153 includes forming a conductive layer that fills the second trench TR2 and performing an etch-back process that removes a portion of the conductive layer. The conductive layer is formed of or includes at least one of a conductive material, such as a doped semiconductor material. For example, the conductive layer is formed of or includes doped polysilicon.

An insulating gapfill layer 155L is formed that fills a remaining portion of the second trench TR2. The insulating gapfill layer 155L covers the semiconductor pattern 153 and the isolation layer 151L. The insulating gapfill layer 155L is formed of or includes at least one of, for example, silicon oxide, silicon nitride, or silicon oxynitride.

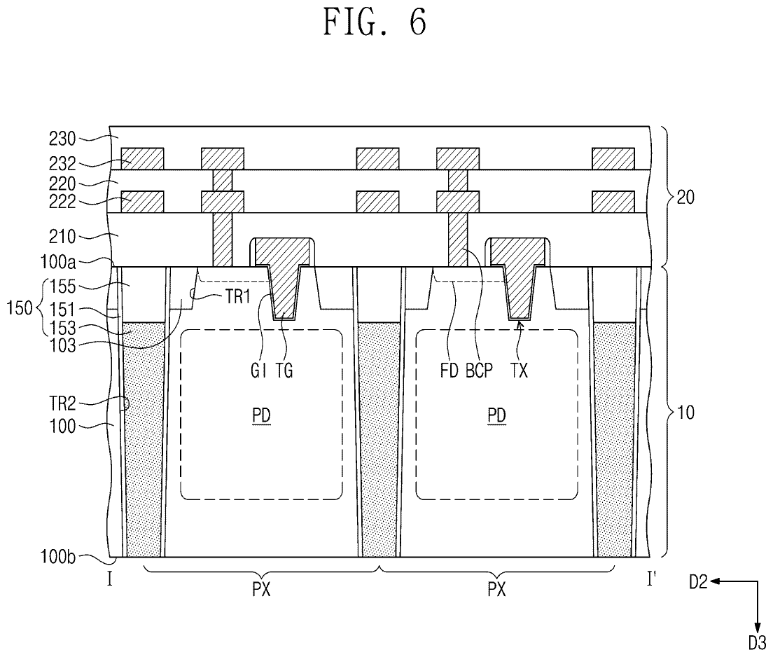

Referring to FIGS. 3 and 6, in an embodiment, a planarization process is performed on the insulating gapfill layer 155L, the isolation layer 151L, and the device isolation layer 103L, until the first surface 100a of the substrate 100 is exposed. The first mask pattern MP ia removed by the planarization process. As a result of the planarization process, the insulating gapfill layer 155L, the isolation layer 151L, and the device isolation layer 103L form the gapfill insulating pattern 155, the isolation pattern 151, and the shallow isolation pattern 103, respectively. Accordingly, the deep isolation pattern 150 is formed.

The photoelectric conversion region PD is formed in each of the pixel regions PX. In an embodiment, the formation of the photoelectric conversion region PD includes injecting impurities of the second conductivity type, such as n-type, that differ from the first conductivity type, such as p-type, into the substrate 100.

The transistors TX, RX, SX, and DX are formed on the first surface 100a of the substrate 100 and on each of the pixel regions PX. In an embodiment, the formation of the transfer transistor TX includes doping a corresponding active region ACT with impurities to form the floating diffusion region FD and forming the transfer gate TG on the corresponding active region ACT. The formation of the drive transistor DX, the selection transistor SX, and the reset transistor RX includes doping corresponding active regions ACT with impurities to form impurity regions and forming the drive gate SFG, the selection gate SG, and the reset gate RG on the corresponding active regions ACT, respectively.

The interconnection layer 20 is formed on the first surface 100a of the substrate 100. For example, the first interlayer insulating layer 210 that covers the transistors TX, RX, SX, and DX is formed on the first surface 100a of the substrate 100 to. The contact plugs BCP are formed in the first interlayer insulating layer 210 and are connected to terminals of the transistors TX, RX, SX, and DX. The second interlayer insulating layer 220 and the third interlayer insulating layer 230 are sequentially formed on the first interlayer insulating layer 210. The first interconnection patterns 222 and the second interconnection patterns 232 are formed in the second interlayer insulating layer 220 and the third interlayer insulating layer 230, respectively. The first and second interconnection patterns 222 and 232 are electrically connected to the transistors TX, RX, SX, and DX through the contact plugs BCP.

A thinning process is performed on the second surface 100b of the substrate 100. The substrate 100 and the deep isolation pattern 150 are partially removed by the thinning process. For example, a lower portion of the deep isolation pattern 150 is removed by the thinning process, and a bottom surface of the deep isolation pattern 150 is substantially coplanar with the second surface 100b of the substrate 100. The photoelectric conversion layer 10 is formed by the afore-described fabrication process.

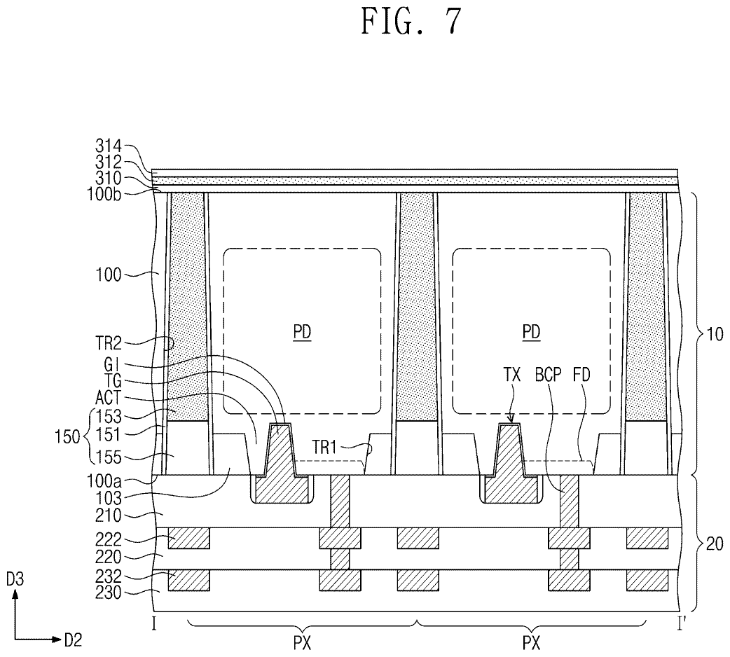

Referring to FIGS. 3 and 7, in an embodiment, the substrate 100 is inverted such that the second surface 100b of the substrate 100 is oriented in an upward direction. The insulating layer 310, the anti-reflection layer 312, and the passivation layer 314 are sequentially formed on the second surface 100b of the substrate 100. The insulating layer 310 is formed to cover the second surface 100b of the substrate 100. The anti-reflection layer 312 is formed to cover the insulating layer 310. The passivation layer 314 is formed to cover the anti-reflection layer 312.

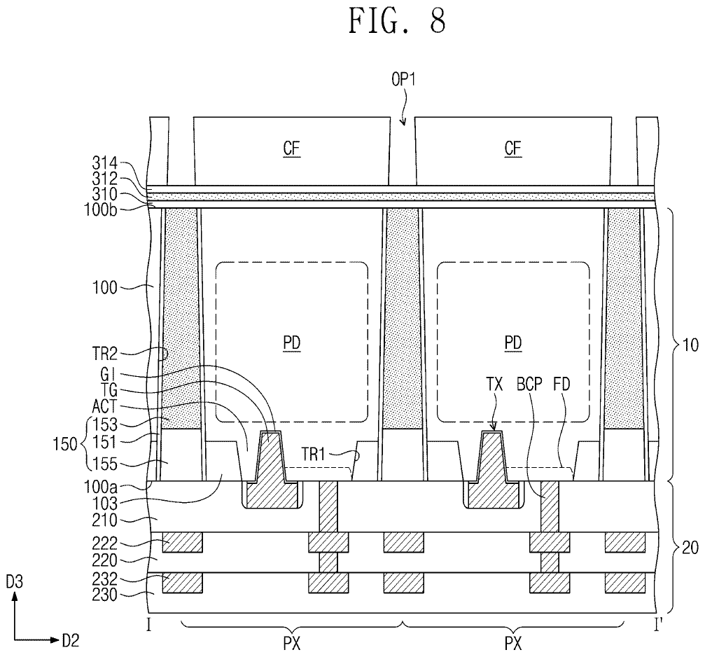

Referring to FIGS. 3 and 8, in an embodiment, the color filters CF are formed on the passivation layer 314. The formation of the color filters CF includes forming a sacrificial layer on the passivation layer 314, patterning the sacrificial layer to form sacrificial patterns and to form openings that expose portions of the passivation layer 314, forming color filters CF that fill the openings, and performing an etching process that removes the sacrificial patterns and forms first openings OP1. In an embodiment, the etching process includes a wet etching process performed using an etchant. The sacrificial pattern are formed of or include at least one of, for example, an oxide material or silicon oxide. The color filters CF are formed between the sacrificial patterns. The color filters CF are spaced apart from each other by the first openings OP1. The color filters CF are formed on respective pixel regions PX, and each of the first openings OP1 vertically overlaps the deep isolation pattern 150.

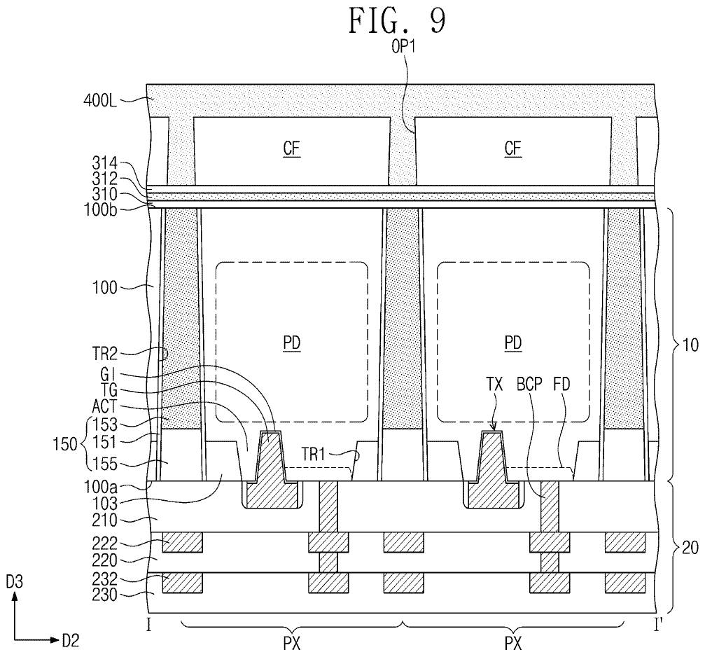

Referring to FIGS. 3 and 9, in an embodiment, a pyrolytic polymer layer 400L is formed on the second surface 100b of the substrate 100. The pyrolytic polymer layer 400L fills the first openings OP1 and covers the color filters CF. The pyrolytic polymer layer 400L includes a carbon-based polymer that contains at least one of oxygen or nitrogen. The pyrolytic polymer layer 400L decomposes into one or more monomers when exposed to heat. For example, the pyrolytic polymer layer 400L decomposes into one or more monomers by a thermal treatment process that is performed at a temperature of from 100° C. to 400° C. or from 170° C. to 230° C. However, embodiments are not necessarily limited thereto, and in an embodiment, the pyrolytic polymer layer 400L may be formed by a chemical vapor deposition (CVD) process or an atomic layer deposition (ALD) process.

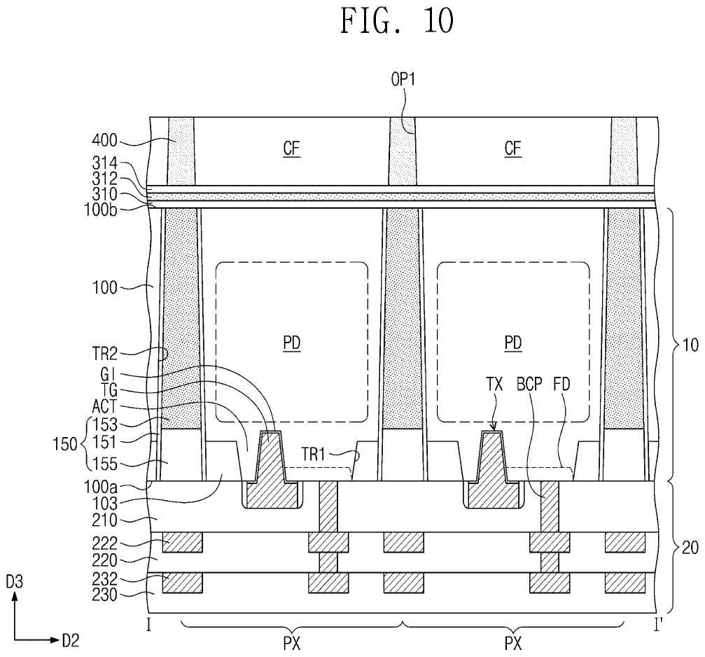

Referring to FIGS. 3 and 10, in an embodiment, a patterning process is performed on the pyrolytic polymer layer 400L that forms pyrolytic polymer patterns 400. The pyrolytic polymer patterns 400 are formed in respective first openings OP1. Each of the pyrolytic polymer patterns 400 is formed between adjacent color filters CF. Top surfaces of the pyrolytic polymer patterns 400 are coplanar with the top surfaces of the color filters CF. The patterning process includes performing an etch-back process that removes a portion of the pyrolytic polymer layer 400L. The etch-back process is performed until a top surface of the pyrolytic polymer layer 400L is coplanar with the top surfaces of the color filters CF. In an embodiment, the etch-back process is performed at a temperature of from 100° C. to 400° C. or from 170° C. to 230° C.

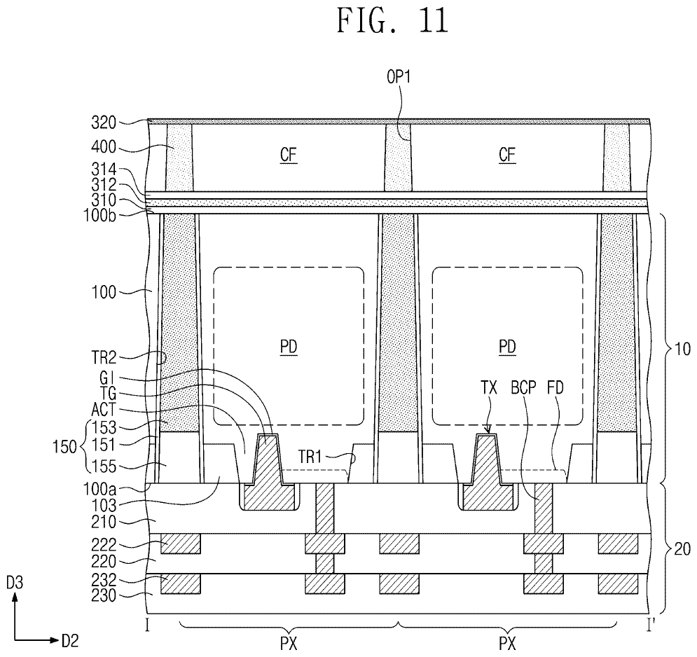

Referring to FIGS. 3 and 11, in an embodiment, the capping layer 320 is formed on the color filters CF. The capping layer 320 covers the color filters CF and the pyrolytic polymer pattern 400. The capping layer 320 has substantially flat top and bottom surfaces. The capping layer 320 is thin enough to facilitate a process of removing the pyrolytic polymer pattern 400 to be described below. For example, a thickness of the capping layer 320 is greater than 0 nm, and less than 30 nm.

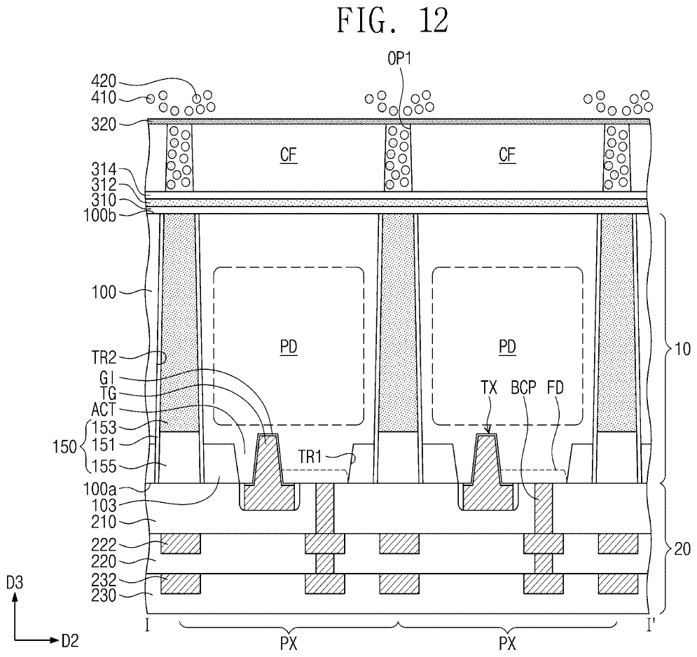

Referring to FIGS. 3 and 12, in an embodiment, a thermal treatment process is performed. The pyrolytic polymer pattern 400 is decomposed into one or more monomers by the thermal treatment process. In an embodiment, the pyrolytic polymer pattern 400 is decomposed into a first monomer 410 and a second monomer 420 by the thermal treatment process. However, the number of the monomers is not necessarily limited to this example. In an embodiment, the decomposed monomers, such as the first and second monomers 410 and 420, move in an upward direction. In an embodiment, the decomposed monomers, such as the first and second monomers 410 and 420 diffuse through the capping layer 320. The thermal treatment process is performed at a temperature between 100° C. and 400° C. or between 170° C. and 230° C. The capping layer 320 is not removed by the thermal treatment process and remains even when the thermal treatment process is finished.

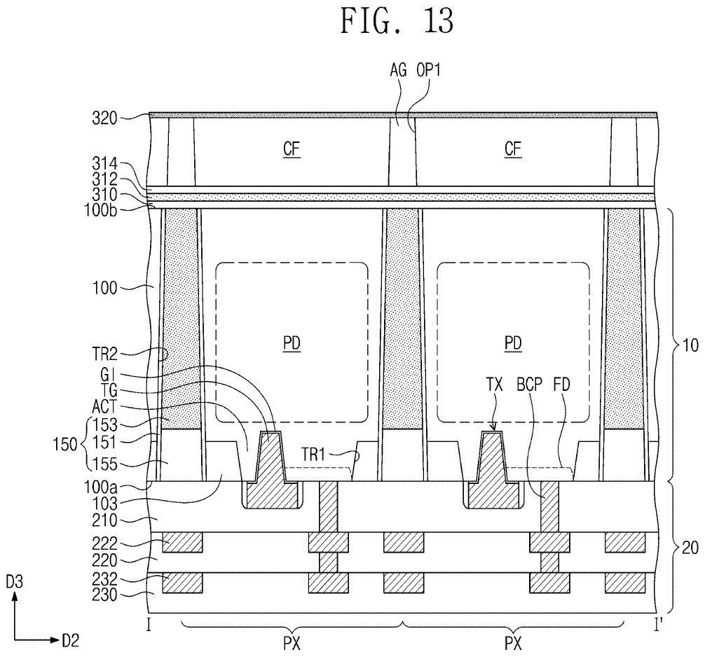

Referring to FIGS. 3 and 13, in an embodiment, the first and second monomers 410 and 420 that move in the upward direction are removed or collected, and thus, the air gap region AG is formed. The air gap region AG is a space that may contain air and that is formed between the color filters CF and between the passivation and capping layers 314 and 320. Since the capping layer 320 is thin, the first and second monomers 410 and 420 are easily removed or collected. For example, the first and second monomers 410 and 420 are removed through the capping layer 320. To sum up, the pyrolytic polymer patterns 400 is removed by a thermal treatment process, and the air gap region AG is formed in place of the pyrolytic polymer patterns 400. In an embodiment, even when the pyrolytic polymer patterns 400 are removed, the bottom surface of the capping layer 320 remains flat. In an embodiment, the first and second monomers 410 and 420 are the same. In an embodiment, the first and second monomers 410 and 420 are different.

Referring back to FIGS. 3 and 4, the micro lenses 330 are formed on the capping layer 320. The optically-transparent layer 30 is formed as a result of the afore-described fabrication process.

According to an embodiment of the inventive concept, the capping layer 320 covers the color filters CF and the pyrolytic polymer patterns 400, and the pyrolytic polymer patterns 400 is removed by a thermal treatment process. Since the bottom surface of the capping layer 320 remains substantially flat, the air gap region AG is formed in a region from which the pyrolytic polymer pattern 400 is removed. The air gap region AG prevents light that is incident into the color filters CF from being reflected or scattered in a lateral direction. For example, the air gap region AG allows for total reflection, which minimizes crosstalk between the pixel regions PX, and improves optical properties of the image sensor.

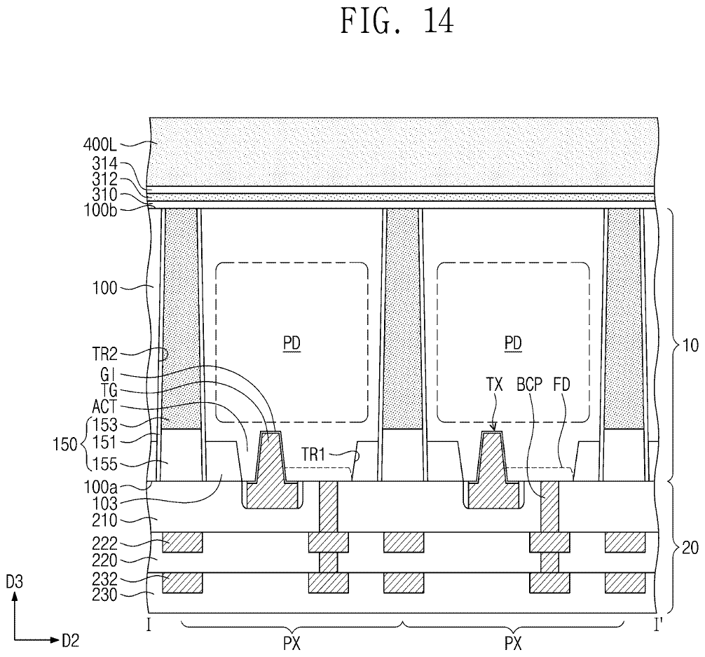

FIGS. 14 to 17 are sectional views that illustrate a method of fabricating an image sensor according to an embodiment of the inventive concept and that correspond to the line I-I′ of FIG. 3. For a concise description, a previously described element may be identified by the same reference number while omitting a repeated description thereof.

Referring to FIGS. 3, 7, and 14, in an embodiment, the insulating layer 310, the anti-reflection layer 312, and the passivation layer 314 are sequentially formed on the second surface 100b of the substrate 100, after the formation of the photoelectric conversion layer 10 and the interconnection layer 20. The pyrolytic polymer layer 400L is formed on the passivation layer 314. The pyrolytic polymer layer 400L covers the passivation layer 314. In an embodiment, the pyrolytic polymer layer 400L is formed by one of a chemical vapor deposition (CVD) process or an atomic layer deposition (ALD) process.

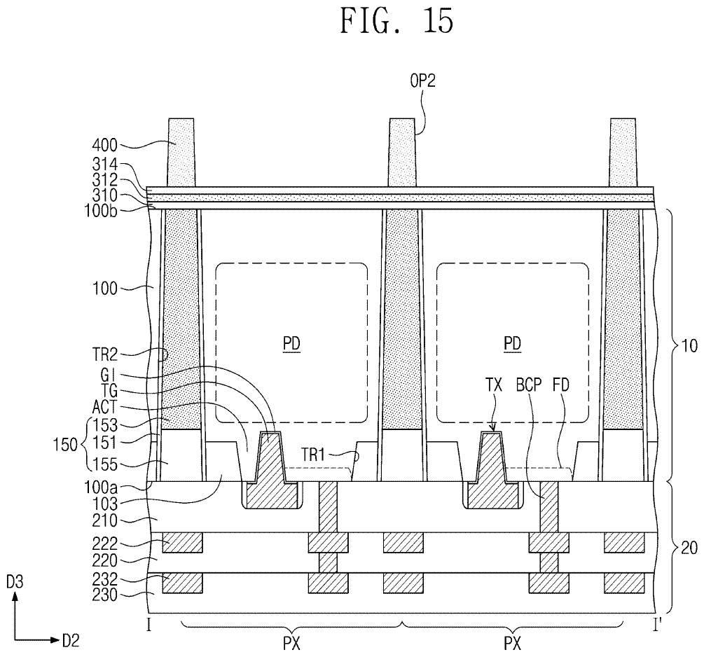

Referring to FIGS. 3 and 15, in an embodiment, the pyrolytic polymer layer 400L is patterned to form the pyrolytic polymer patterns 400. The patterning process includes forming a third mask pattern on the pyrolytic polymer layer 400L and etching the pyrolytic polymer layer 400L using the third mask pattern as an etch mask. The pyrolytic polymer layer 400L is partially removed by the etching process, and second openings OP2 are formed between adjacent pyrolytic polymer patterns 400 that expose portions of the passivation layer 314.

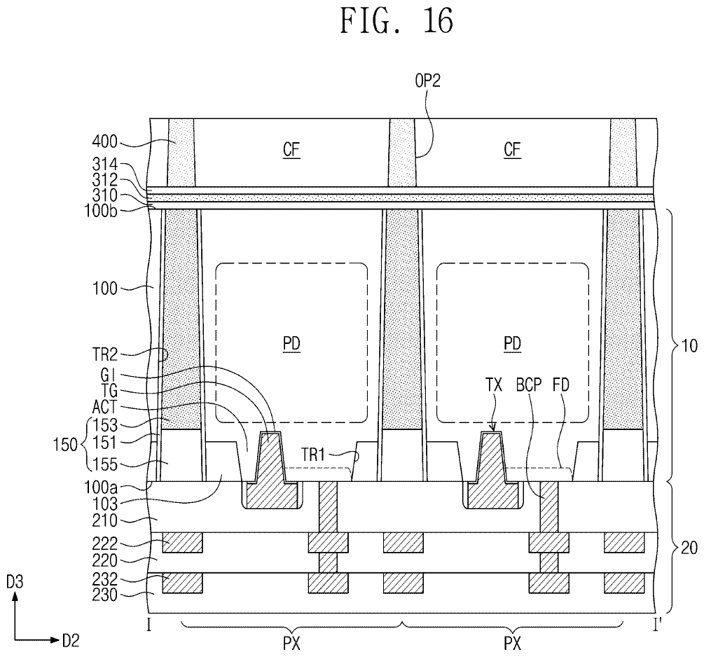

Referring to FIGS. 3 and 16, in an embodiment, the color filters CF are formed on the passivation layer 314. The color filters CF are formed in respective second openings OP2. The color filters CF have top surfaces that are coplanar with the top surfaces of the pyrolytic polymer patterns 400.

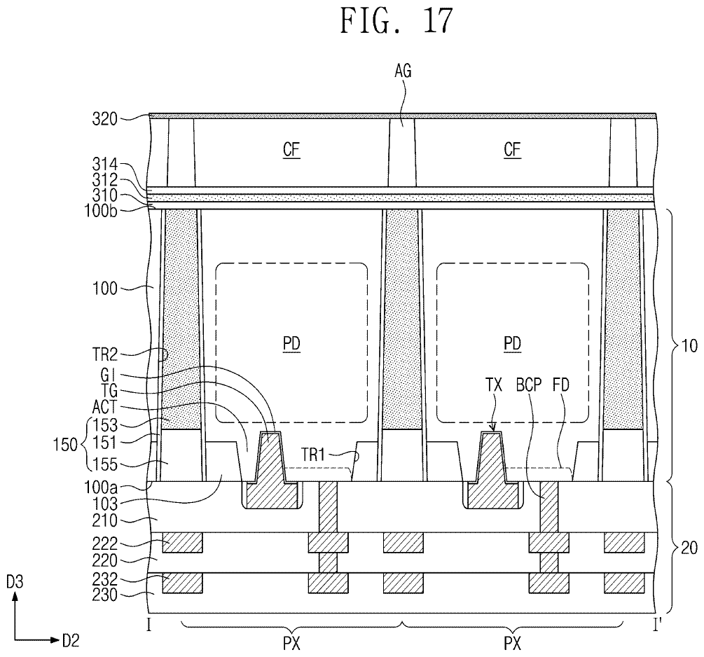

Referring to FIGS. 3 and 17, in an embodiment, the capping layer 320 is formed on the color filters CF. The capping layer 320 covers the color filters CF and the pyrolytic polymer pattern 400. The capping layer 320 has substantially flat top and bottom surfaces. The capping layer 320 is thin, which facilitates a process of removing the pyrolytic polymer pattern 400 to be described below.

Referring to FIGS. 3 and 12, a thermal treatment process is performed. The pyrolytic polymer pattern 400 is decomposed into one or more monomers by the thermal treatment process. The decomposed monomers move in an upward direction. In an embodiment, the decomposed monomers are removed through the capping layer 320. The monomers are removed or collected, and the air gap region AG is formed. The thermal treatment process is performed at a temperature between 100° C. and 400° C. or between 170° C. and 230° C. The capping layer 320 is not removed by the thermal treatment process and remains even after the thermal treatment process finishes. Accordingly, the air gap region AG, which is a space that may contain air, is formed between the color filters CF and between the passivation and capping layers 314 and 320. Since the capping layer 320 is thin, the pyrolytic polymer pattern 400 is easily removed or collected. For example, the capping layer 320 is thin enough to allow the monomers to pass therethrough, such that the monomers can be removed through the capping layer 320. For example, the pyrolytic polymer patterns 400 are removed by the thermal treatment process, and the air gap region AG is formed in place of the pyrolytic polymer patterns 400. In an embodiment, even when the pyrolytic polymer patterns 400 are removed, the bottom surface of the capping layer 320 remains flat.

Referring back to FIGS. 3 and 4, the micro lenses 330 are formed on the capping layer 320. The optically-transparent layer 30 is formed by the afore-described fabrication process.

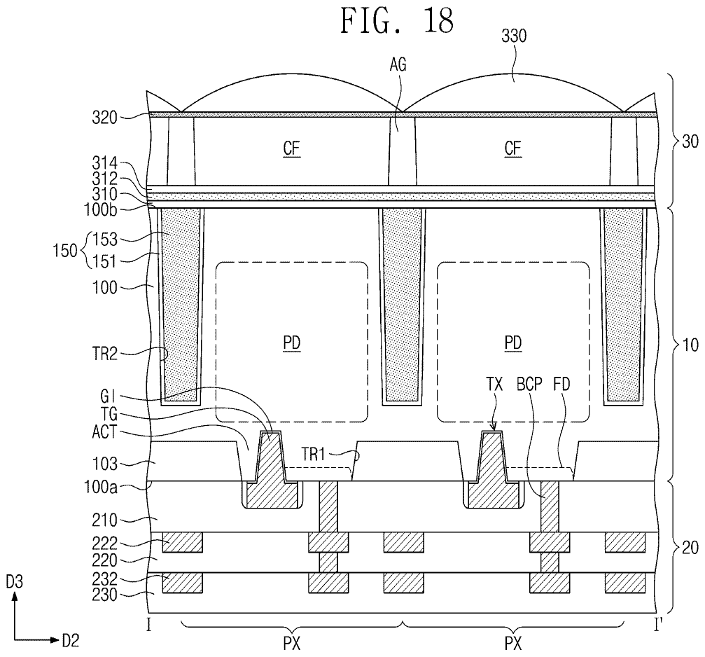

FIG. 18 is a sectional view taken along the line I-I′ of FIG. 3 of an image sensor according to an embodiment of the inventive concept. For the sake of brevity, the same element as in an image sensor previously described with reference to FIGS. 1 to 4 may be identified by the same reference number while omitting a repeated description thereof.

Referring to FIGS. 3 and 18, in an embodiment, an image sensor includes the photoelectric conversion layer 10, the interconnection layer 20, and the optically-transparent layer 30.

The photoelectric conversion layer 10 includes the substrate 100 with the pixel regions PX. The substrate 100 includes the deep isolation pattern 150 that is disposed in the second trench TR2 and between the pixel regions PX. The deep isolation pattern 150 extends from the second surface 100b of the substrate 100 toward the first surface 100a of the substrate 100. The deep isolation pattern 150 has a bottom surface that is located at a higher level than the first surface 100a of the substrate 100. The bottom surface of the deep isolation pattern 150 is spaced apart from the shallow isolation pattern 103. The deep isolation pattern 150 includes the isolation pattern 151 that conformally covers inner side surfaces and a bottom surface of the second trench TR2, and the semiconductor pattern 153 that fills a remaining portion of the second trench TR2.

The optically-transparent layer 30 includes the color filters CF and the micro lenses 330. The optically-transparent layer 30 also includes the air gap region AG, which is a space that may contain air and is interposed between the color filters CF and between the passivation and capping layers 314 and 320.

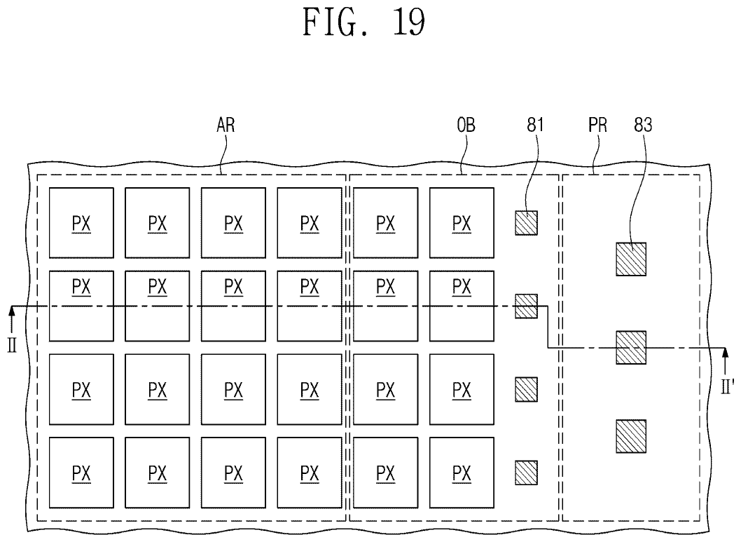

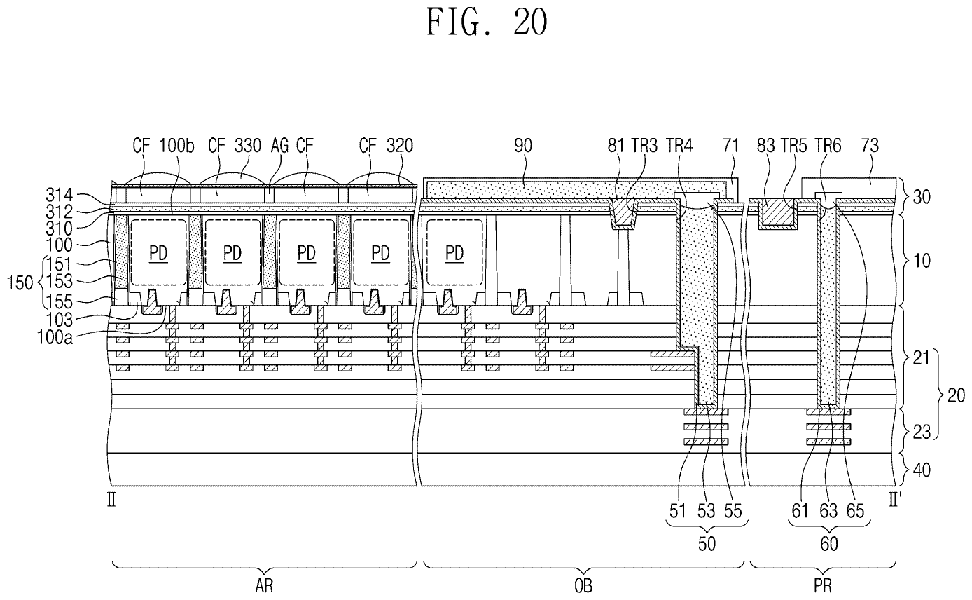

FIG. 19 is a plan view of an image sensor according to an embodiment of the inventive concept. FIG. 20 is a sectional view taken along a line II-II′ of FIG. 19 of an image sensor according to an embodiment of the inventive concept.

Referring to FIGS. 19 and 20, in an embodiment, an image sensor includes the substrate 100 that includes a pixel array region AR, an optical black region OB, and a pad region PR, the interconnection layer 20 on the first surface 100a of the substrate 100, a base substrate 40 on the interconnection layer 20, and the optically-transparent layer 30 on the second surface 100b of the substrate 100. The interconnection layer 20 is disposed between the first surface 100a of the substrate 100 and the base substrate 40. The interconnection layer 20 includes an upper interconnection layer 21 provided adjacent to the first surface 100a of the substrate 100, and a lower interconnection layer 23 provided between the upper interconnection layer 21 and the base substrate 40. The pixel array region AR includes the pixel regions PX and the deep isolation pattern 150 therebetween. The pixel array region AR is substantially the same as that in an image sensor described with reference to FIGS. 1 to 5. For example, the optically-transparent layer 30includes the color filters CF, the micro lenses 330, and the air gap region AG, which is a space between the color filters CF and between the passivation and capping layers 314 and 320 that may contain air.

A first connection structure 50, a first contact 81, and a bulk color filter 90 are disposed on the optical black region OB of the substrate 100. The first connection structure 50 includes a first light-blocking pattern 51, a first isolation pattern 53, and a first capping pattern 55. The first light-blocking pattern 51 is disposed on the second surface 100b of the substrate 100. The first light-blocking pattern 51 covers the passivation layer 314 and conformally covers an inner surface of each of third and fourth trenches TR3 and TR4. The first light-blocking pattern 51 penetrates the photoelectric conversion layer 10 and the upper interconnection layer 21. The first light-blocking pattern 51 is connected to the deep isolation pattern 150 of the photoelectric conversion layer 10 and is connected to interconnection lines in the upper and lower interconnection layers 21 and 23. Accordingly, the first connection structure 50 electrically connects the photoelectric conversion layer 10 to the interconnection layer 20. The first light-blocking pattern 51 is formed of or includes at least one metal, such as tungsten. The first light-blocking pattern 51 blocks light that is incident into the optical black region OB.

The first contact 81 fills a remaining portion of the third trench TR3. The first contact 81 is formed of or include at least one metal, such as aluminum. The first contact 81 is connected to the deep isolation pattern 150. The first isolation pattern 53 fills a remaining portion of the fourth trench TR4. The first isolation pattern 53 penetrates the photoelectric conversion layer 10 and a portion of the interconnection layer 20. The first isolation pattern 53 is formed of or includes at least one insulating material. The first capping pattern 55 is disposed on the first isolation pattern 53.

The bulk color filter 90 is disposed on the first connection structure 50 and the first contact 81. The bulk color filter 90 covers the first connection structure 50 and the first contact 81. A first protection layer 71 is disposed on the bulk color filter 90 that hermetically seals the bulk color filter 90.

The photoelectric conversion region PD is provided in a corresponding pixel region PX of the optical black region OB. The photoelectric conversion region PD of the optical black region OB is doped to have the second conductivity type, such as n-type, that differs from the first conductivity type of the substrate 100. The photoelectric conversion region PD of the optical black region OB has a structure that is similar to that of the photoelectric conversion regions PD of the pixel array region AR, but does not generate electrical signals from light, unlike the photoelectric conversion regions PD of the pixel array region AR.

A second connection structure 60, a second contact 83, and a second protection layer 73 are disposed on the pad region PR of the substrate 100. The second connection structure 60 includes a second light-blocking pattern 61, a second isolation pattern 63, and a second capping pattern 65.

The second light-blocking pattern 61 is disposed on the second surface 100b of the substrate 100. The second light-blocking pattern 61 covers the passivation layer 314 and conformally covers an inner surface of each of fifth and sixth trenches TR5 and TR6. The second light-blocking pattern 61 penetrates the photoelectric conversion layer 10 and the upper interconnection layer 21. The second light-blocking pattern 61 is connected to the interconnection lines in the lower interconnection layer 23. Accordingly, the second connection structure 60 electrically connects the photoelectric conversion layer 10 to the interconnection layer 20. The second light-blocking pattern 61 is formed of or includes at least one metal, such as tungsten. The second light-blocking pattern 61 blocks light that is incident into the pad region PR.

The second contact 83 fills a remaining portion of the fifth trench TR5. The second contact 83 is formed of or includes at least one metal, such as aluminum. The second contact 83 provides an electric connection path between the image sensor and an external device. The second isolation pattern 63 fills a remaining portion of the sixth trench TR6. The second isolation pattern 63 penetrates the photoelectric conversion layer 10 and penetrates a portion of the interconnection layer 20. The second isolation pattern 63 is formed of or includes at least one insulating material. The second capping pattern 65 is disposed on the second isolation pattern 63. The second protection layer 73 covers the second connection structure 60.

A current that is applied through the second contact 83 flows to the deep isolation pattern 150 through the second light-blocking pattern 61, the interconnection lines in the interconnection layer 20, and the first light-blocking pattern 51. Electrical signals that are generated by the photoelectric conversion regions PD in the pixel regions PX of the pixel array region AR are output through the interconnection lines in the interconnection layer 20, the second light-blocking pattern 61, and the second contact 83.

In a method of fabricating an image sensor according to an embodiment of the inventive concept, a capping layer is formed that covers color filters and pyrolytic polymer patterns, and the pyrolytic polymer patterns is removed by a thermal treatment process. Here, since a bottom surface of the capping layer remains substantially flat, an air gap region is formed in a region from which the pyrolytic polymer pattern is removed. The air gap region prevents light that is incident into the color filters from being laterally reflected or scattered. For example, the air gap region allows total reflection, and thus minimizes crosstalk between pixel regions. In this case, the image sensor has improved optical properties.

While embodiments of the inventive concept have been particularly shown and described, it will be understood by one of ordinary skill in the art that variations in form and detail may be made therein without departing from the spirit and scope of the attached claims.

1-20. (canceled)

21. An image sensor comprising:
a substrate comprising a first surface and a second surface opposing the first surface;
a first photoelectric conversion region (PD) in the substrate;
a second PD in the substrate;
an isolation pattern between the first and second PDs;
an insulating layer on the second surface;
an anti-reflection layer on the insulating layer;
a passivation layer on the anti-reflection layer;
a first color filter on the first PD and the passivation layer;
a second color filter on the second PD and the passivation layer; and
an air gap region between the first and second color filters and comprising a top surface and a bottom surface opposing the top surface,
wherein a distance from the second surface to a top surface of the anti-reflection layer in a first direction perpendicular to the second surface is shorter than a width of the top surface of the air gap region in a second direction perpendicular to the first direction,
wherein a distance from second surface to the bottom surface of the air gap region in the first direction is shorter than a distance from the second surface to the top surface of the air gap region in the first direction,
wherein a distance from second surface to a bottom surface of the anti-reflection layer in the first direction is shorter than a distance from the second surface to the top surface of the anti-reflection layer in the first direction, and
wherein the insulating layer, the anti-reflection layer, and the passivation layer are sequentially arranged in the first direction.

22. The image sensor of claim 21, further comprising:
a capping layer on the top surface of the air gap region,
wherein a height of the capping layer in the first direction is shorter than the width of the top surface of the air gap region in the second direction.

23. The image sensor of claim 22, wherein the anti-reflection layer comprises a metal oxide material.

24. The image sensor of claim 23, wherein the anti-reflection layer comprises aluminum oxide.

25. The image sensor of claim 23, wherein a height of the air gap region in the first direction is greater than a distance from the second surface to a top surface of the passivation layer in the first direction, and
wherein a distance from second surface to a bottom surface of the passivation layer in the first direction is shorter than a distance from the second surface to the top surface of the passivation layer in the first direction.

26. The image sensor of claim 25, wherein the width of the top surface of the air gap region in the second direction is shorter than a width of the bottom surface of the air gap region in the second direction.

27. The image sensor of claim 25, wherein the isolation pattern penetrates the substrate.

28. The image sensor of claim 27, further comprising:
a transfer gate disposed between the first PD and the first surface,
wherein the transfer gate extends into the substrate from the first surface.

29. The image sensor of claim 25, wherein the isolation pattern comprises a top surface and a bottom surface opposing the top surface in the first direction, and
wherein a width of the top surface of the isolation pattern in the second direction is greater than the width of the top surface of the air gap region in the second direction.

30. The image sensor of claim 29, wherein a width of the bottom surface of the isolation pattern in the second direction is greater than the width of the bottom surface of the air gap region in the second direction.

31. An image sensor comprising:
a substrate comprising a first surface and a second surface opposing the first surface;
a first photoelectric conversion region (PD) in the substrate;
a second PD in the substrate;
an isolation pattern between the first and second PDs;
an insulating layer on the second surface;
an anti-reflection layer on the insulating layer;
a first color filter on the first PD and the anti-reflection layer;
a second color filter on the second PD and the anti-reflection layer; and
an air gap region) between the first and second color filters and comprising a top surface and a bottom surface opposing the top surface,
wherein a distance from the second surface to a top surface of the anti-reflection layer in a first direction perpendicular to the second surface is shorter than a width of the top surface of the air gap region in a second direction perpendicular to the first direction,
wherein a distance from second surface to the bottom surface of the air gap region in the first direction is shorter than a distance from the second surface to the top surface of the air gap region in the first direction,
wherein a distance from second surface to a bottom surface of the anti-reflection layer in the first direction is shorter than a distance from the second surface to the top surface of the anti-reflection layer in the first direction,
wherein the insulating layer and the anti-reflection layer are sequentially arranged in the first direction,
wherein the isolation pattern comprises a top surface and a bottom surface opposing the top surface in the first direction, and
wherein a width of the top surface of the isolation pattern in the second direction is greater than the width of the top surface of the air gap region in the second direction.

32. The image sensor of claim 31, wherein the anti-reflection layer comprises a metal oxide material.

33. The image sensor of claim 32, wherein the anti-reflection layer comprises aluminum oxide.

34. The image sensor of claim 32, wherein the anti-reflection layer comprises hafnium oxide.

35. The image sensor of claim 33, further comprising:
a passivation layer on the anti-reflection layer.

36. The image sensor of claim 33, further comprising:
a capping layer on the top surface of the air gap region,
wherein a height of the capping layer in the first direction is shorter than the width of the top surface of the air gap region in the second direction.

37. The image sensor of claim 36, wherein the capping layer comprises at least one of an oxide, a nitride, silicon oxide, and silicon nitride.

38. The image sensor of claim 36, wherein the width of the top surface of the air gap region in the second direction is shorter than a width of the bottom surface of the air gap region in the second direction.

39. An image sensor comprising:
a substrate comprising a first surface and a second surface opposing the first surface;
a first photoelectric conversion region (PD) in the substrate;
a second PD in the substrate;
an isolation pattern between the first and second PDs;
an insulating layer on the second surface;
an anti-reflection layer on the insulating layer;
a passivation layer on the anti-reflection layer;
a first color filter on the first PD and the passivation layer;
a second color filter on the second PD and the passivation layer; and
an air gap region between the first and second color filters and comprising a top surface and a bottom surface opposing the top surface,
wherein a distance from the second surface to a top surface of the anti-reflection layer in a first direction perpendicular to the second surface is shorter than a width of the top surface of the air gap region in a second direction perpendicular to the first direction,
wherein a distance from second surface to the bottom surface of the air gap region in the first direction is shorter than a distance from the second surface to the top surface of the air gap region in the first direction,
wherein a distance from second surface to a bottom surface of the anti-reflection layer in the first direction is shorter than a distance from the second surface to the top surface of the anti-reflection layer in the first direction,
wherein the insulating layer, the anti-reflection layer, and the passivation layer are sequentially arranged in the first direction, and
wherein the width of the top surface of the air gap region in the second direction is shorter than a width of the bottom surface of the air gap region in the second direction.

40. The image sensor of claim 39, further comprising:
a capping layer on the top surface of the air gap region,
wherein the capping layer comprises at least one of an oxide, a nitride, silicon oxide, and silicon nitride.
